(19) United States
(12) Patent Application Publication
(10) Pub. No.: US 2025/0379178 A1
(43) Pub. Date: Dec. 11, 2025

(54) MODULE CONTAINING FAN-OUT WAFER-LEVEL PACKAGING (FOWLP) UNIT CONNECTED TO ELECTRONIC COMPONENT BY WIRE BONDING

(71) Applicant: WALTON ADVANCED ENGINEERING, INC., KAOHSIUNG (TW)

(72) Inventors: HONG-CHI YU, KAOHSIUNG (TW); CHUN-JUNG LIN, KAOHSIUNG (TW); RUEI-TING GU, KAOHSIUNG (TW)

(21) Appl. No.: 19/224,924

(22) Filed: Jun. 2, 2025

(30) Foreign Application Priority Data
Jun. 6, 2024 (TW) 113121098

(51) Int. Cl. H01L 23/00; H01L 21/48; H01L 23/14; H01L 23/15; H01L 23/498; H01L 23/538; H01L 25/065; H05K 1/18

(52) U.S. Cl. CPC H01L 24/48; H01L 21/4853; H01L 23/147; H01L 23/15; H01L 23/49866; H01L 23/5386; H01L 24/08; H01L 24/32; H01L 24/73; H01L 24/97; H01L 25/0657; H05K 1/181; H01L 2224/08225; H01L 2224/32225; H01L 2224/48091; H01L 2224/48225; H01L 2224/48464; H01L 2224/73265; H01L 2224/97; H01L 2225/0651; H01L 2225/06524; H01L 2924/15165; H01L 2924/15787; H01L 2924/15788; H01L 2924/15791

(57) ABSTRACT

A module containing a fan-out wafer-level packaging unit connected to an electronic component by wire bonding and having a substrate, a first die, a first dielectric layer, first conductive circuits, a second dielectric layer, second conductive circuits, a second die, an electronic component, at least one first bonding wire, at least two second bonding wires, and at least one third bonding wire is provided. The second conductive circuits are formed by grinding of a metal paste filled in a plurality of second slots of the second dielectric layer. The second conductive circuits form bonding pads in the second slots. The first die is electrically connected to the outside by the bonding pads around a chip area of a second surface of the first die. Thereby the problems generated during manufacturing of the conductive circuits including higher manufacturing cost and less environmental benefit are solved.

### CROSS-REFERENCE TO RELATED APPLICATIONS

This non-provisional application claims priority under 35 U.S.C. § 119 (a) on Patent Application No(s). 113121098 filed in Taiwan, R.O.C. on Jun. 6, 2024, the entire contents of which are hereby incorporated by reference.

### BACKGROUND OF THE INVENTION

The present invention relates to a module, especially to a module in which a fan-out wafer level packaging (FOWLP) unit is connected to an electronic component by wire bonding.

Packaging technology with features of compact design, high efficiency and reliability is a trend in semiconductor industry. In the semiconductor packaging, Fan-Out Wafer Level Packaging (FOWLP) is a packaging technology available now.

In the advanced packaging process such as FOWLP, a redistribution layer (RDL) is the most critical because respective conductive circuits in the RDL make a plurality of die pads on dies have electrical extension in the XY plane and interconnections. Thus a plurality of bonding pads is arranged around the die in a more distributed manner. Thereby design, space, and reliability of the respective conductive circuits are effectively improved. Yet how to keep balance between the electrical extension in the XY plane and interconnections of the conductive circuits and the compact design to a certain degree, the most critical point is the manufacturing of the respective conductive circuits in the RDL.

However, the formation of the respective conductive circuits in the RDL of the FOWLP technology available now is by chemical plating or electroplating. Thus not only cost for material and manufacturing is high, the manufacturing process is also not environmental friendly.

Moreover, the amount of dies must be increased in order to increase performance or computation ability of a FOWLP unit. How to form electrical connection between dies inside a packaging unit and the outside as well as dies outside the packaging unit and the inside is also a critical issue which needs to be addressed.

### SUMMARY OF THE INVENTION

Therefore, it is a primary object of the present invention to provide a module containing a fan-out wafer-level packaging (FOWLP) unit connected to an electronic component by wire bonding. The module includes a substrate, a first die, a first dielectric layer, a plurality of first conductive circuits, a second dielectric layer, a plurality of second conductive circuits, a second die, an electronic component, at least one first bonding wire, at least two second bonding wires, and at least one third bonding wire. The respective second conductive circuits are formed by grinding of a metal paste filled in a plurality of second slots of the second dielectric layer and the respective second conductive circuits form bonding pads in the respective second slots. The first die is electrically connected to the outside by the bonding pads around a chip area of a second surface of the first die. Thereby the problems of the FOWLP technology in the module available now generated during manufacturing of the respective conductive circuits including higher manufacturing cost and less environmental benefit can be solved.

In order to achieve the above object, a module in which a fan-out wafer level packaging (FOWLP) unit is connected to an electronic component by wire bonding. The module includes a substrate, a first die, a first dielectric layer, a plurality of first conductive circuits, a second dielectric layer, a plurality of second conductive circuits, a second die, an electronic component, at least one first bonding wire, at least two second bonding wires, and at least one third bonding wire. The substrate is provided with a first surface and a second surface opposite to each other. The first die is cut from a wafer and provided with a first surface and a second surface opposite to the first surface. The first surface of the first die is fixed on the second surface of the substrate while the second surface of the first die is provided with a plurality of die pads. A range perpendicular to the second surface of the first die is defined as a chip area. The first dielectric layer is mounted to the second surface of the substrate and the second surface of the first die and provided with a plurality of first slots extending in a horizontal direction. The respective die pads of the first die are exposed through the respective first slots. The respective first conductive circuits are formed by a metal paste filled in the respective first slots and electrically connected with the respective die pads of the first die. The respective first conductive circuits are electrically connected to the die pads of the first die. The second dielectric layer is disposed over the first dielectric layer and provided with a plurality of second slots each of which is extending in a horizontal direction and communicating with the corresponding first slot. The respective second conductive circuits are formed by a metal paste filled in the respective second slots and electrically connected with the first conductive circuits correspondingly. At least one of the second slots is located around the chip area on the second surface of the first die. Each of the second conductive circuits is exposed through the corresponding second slot to form a bonding pad in the second slot. The first die is electrically connected to the outside through the die pads of the first die, the first conductive circuits, the second conductive circuits, and the bonding pads located around the chip area on the second surface of the first die in turn. The second die is cut from a wafer and provided with a first surface and a second surface opposite to each other. The first surface of the second die is fixed on the second dielectric surface. Thereby the fan-out wafer-level packaging (FOWLP) unit is formed. The second surface of the second die is provided with a plurality of die pads. The electronic component is provided with a first surface for mounting the first surface of the substrate. The first bonding wire forms a first bonding point and a second bonding point respectively on the bonding pad and the die pad of the second die by a wire bonding process. Thereby an electrical connection is formed between the first die and the second die of the FOWLP unit. The second bonding wire forms a third bonding point and a fourth bonding point respectively on the bonding pad around the chip area and the first surface of the electronic component by the wire bonding process so that both the first die and the second die of the FOWLP unit are electrically connected with the electronic component. The third bonding wire forms a fifth bonding point and a sixth bonding point respectively on the die pads of the second die and the first surface of the electronic component by the wire bonding process so that the second die of the FOWLP unit and the electronic component are electrically connected. A method of manufacturing the module includes the following steps. Step S1: providing a substrate. The substrate includes a first surface and a second surface opposite to the first surface. Step S2: arranging a plurality of first dies cut from at least one wafer at the substrate and the first dies are spaced a part from one another. Each of the first dies includes a first surface and a second surface opposite to the first surface. The first surface of the first die is arranged at the substrate while the second surface of the first die is provided with a plurality of die pads. A range perpendicular to the second surface of the first die is defined as a chip area. Step S3: paving a first dielectric layer over the substrate and the second surface of the respective first dies and forming a plurality of first slots extending horizontally on the first dielectric layer so that the respective die pads of the respective first dies are exposed through the respective first slots. Then filling a metal paste into the respective first slots and allowing a level of the metal paste higher than a surface of the first dielectric layer. Next grinding the metal paste with the level higher than the surface of the first dielectric layer to make a surface of the metal paste flush with the surface of the first dielectric layer and form a plurality of first conductive circuits. Later arranging a second dielectric layer over the first dielectric layer and forming a plurality of second slots which are extending horizontally on the second dielectric layer and communicating with the first slots correspondingly. At least one of the second slots is formed around the chip area on the second surface of the first die. Lastly, filling a metal paste into the respective second slots, allowing a level of the metal paste higher than a surface of the second dielectric layer, and grinding the metal paste with the level higher than the surface of the second dielectric layer to make a surface of the metal paste flush with the surface of the second dielectric layer and form a plurality of second conductive circuits. Each of the second conductive circuits can be exposed through the corresponding second slot to form a bonding pad in the second slot. Step S4: disposing a second die on the second dielectric layer. The second die includes a first surface and a second surface opposite to each other. The first surface of the second die is fixed on the second dielectric layer and the second surface of the second die is provided with a plurality of die pads. Step S5: performing cutting to form a plurality of fan-out wafer-level packaging (FOWLP) units. Each of the FOWLP units includes the first die and the second die. Step S6: providing an electronic component which includes a first surface and disposing the first surface of the substrate of one of the FOWLP units on the first surface of the electronic component. Step S7: performing a wire bonding process to make at least one first bonding wire, at least two second bonding wires, and at least one third bonding wire form on the FOWLP unit or the electronic component. The first bonding wire forms a first bonding point and a second bonding point respectively on the bonding pad of the first die and the die pad of the second die of the FOWLP unit. The second bonding wire forms a third bonding point and a fourth bonding point respectively on the bonding pad around the chip area of the FOWLP unit and the electronic component. The third bonding wire forms a fifth bonding point and a sixth bonding point respectively on the die pad of the second die and the first surface of the electronic component. The first die and the second die in the FOWLP unit on the electronic component are electrically connected by the first bonding wire. Both the first die and the second die of the FOWLP unit on the electronic component are electrically connected with the electronic component by the second bonding wire. The second die of the FOWLP unit and the electronic component are electrically connected by the third bonding wire. Thereby the module is formed.

### BRIEF DESCRIPTION OF THE DRAWINGS

FIG. 1 is a side sectional view of a module of an embodiment according to the present invention;

FIG. 2 is a side sectional view showing a first die arranged at a substrate of an embodiment according to the present invention;

FIG. 3 is a side sectional view showing a first dielectric layer paved over the first die of an embodiment according to the present invention;

FIG. 4 is a side sectional view showing first slots filled with a metal paste of the embodiment in FIG. 3 according to the present invention;

FIG. 5 is a side sectional view showing first conductive circuits formed by grinding of the metal paste of the embodiment in FIG. 4 according to the present invention;

FIG. 6 is a side sectional view showing a second dielectric layer paved over the first dielectric layer of the embodiment in FIG. 5 according to the present invention;

FIG. 7 is a side sectional view showing second slots filled with a metal paste of the embodiment in FIG. 6 according to the present invention;

FIG. 8 is a side sectional view showing second conductive circuits formed by grinding of the metal paste of the embodiment in FIG. 7 according to the present invention;

FIG. 9 is a side sectional view showing a second die disposed over the second dielectric layer of the embodiment in FIG. 8 according to the present invention.

### DETAILED DESCRIPTION OF THE PREFERRED EMBODIMENT

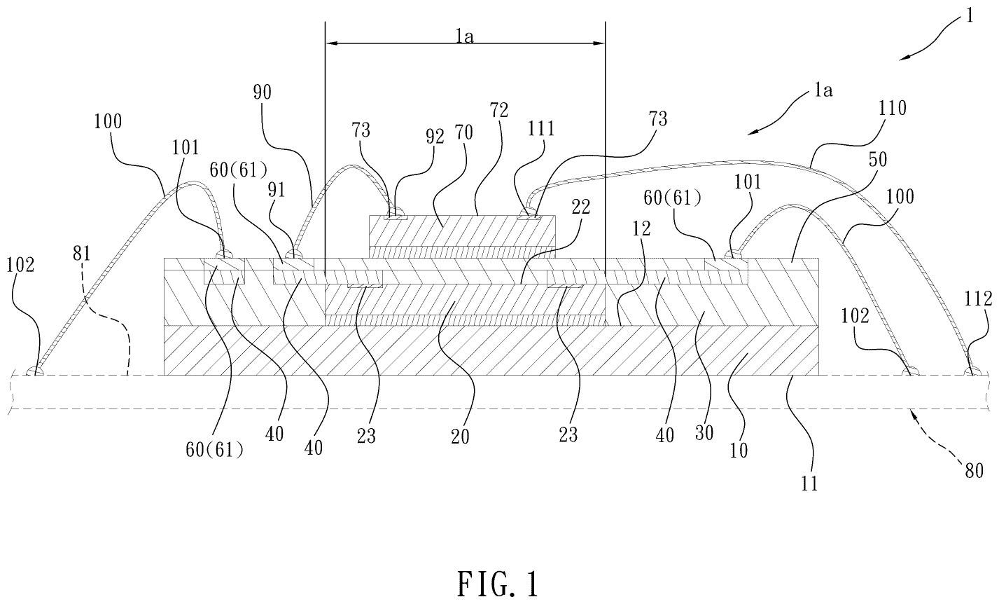

Refer to FIG. 1, a module containing a fan-out wafer-level packaging (FOWLP) unit connected to an electronic component by wire bonding 1 according to the present invention is provided. The module 1 includes a substrate 10, a first die 20, a first dielectric layer 30, a plurality of first conductive circuits 40, a second dielectric layer 50, a plurality of second conductive circuits 60, a second die 70, an electronic component 80, at least one first bonding wire 90, at least two second bonding wires 100, and at least one third bonding wire 110.

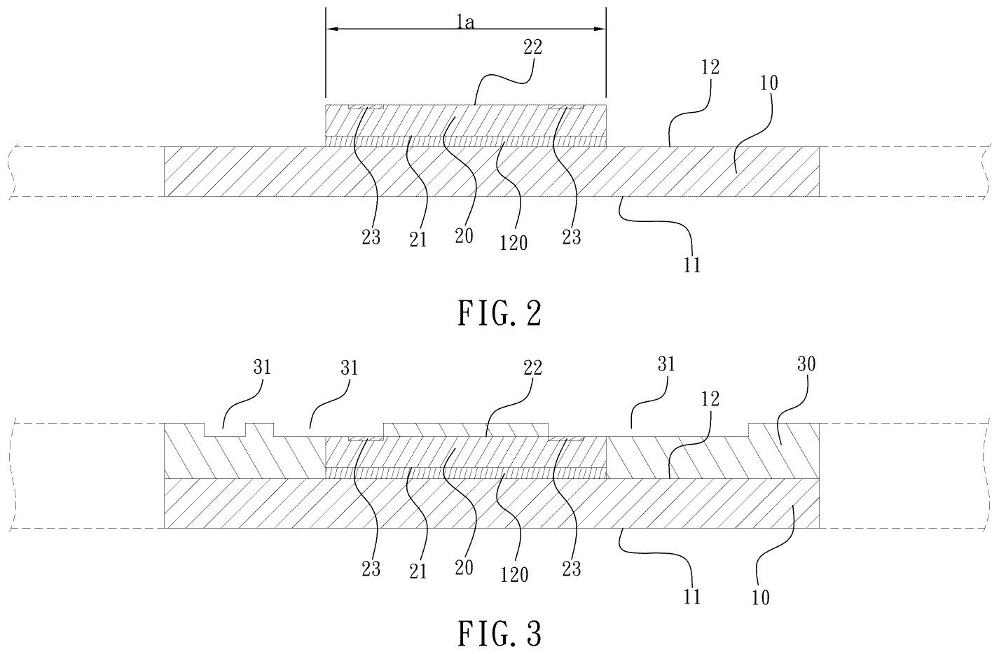

The substrate 10 is provided with a first surface 11 and a second surface 12 opposite to each other, as shown in FIG. 2.

The first die 20 is cut from a wafer and provided with a first surface 21 and a second surface 22 opposite to the first surface 21. The first surface 21 of the first die 20 is fixed on the second surface 12 of the substrate 10 while the second surface 22 of the first die 20 is provided with a plurality of die pads 23. As shown in FIG. 2, a range perpendicular to the second surface 22 of the first die 20 is defined as a chip area 1a. In FIG. 2, there are two die pads 23 on the first die 20 but the number of the die pads 23 is not limited.

Refer to FIG. 3, the first dielectric layer 30 is mounted to the second surface 12 of the substrate 10 and the second surface 22 of the first die 20 and provided with a plurality of first slots 31 extending in a horizontal direction. The respective die pads 23 of the first die 20 are exposed through the respective first slots 31, as shown in FIG. 3.

The respective first conductive circuits 40 are formed by a metal paste 40a filled in the respective first slots 31. As shown in FIG. 5, the respective first conductive circuits 40 are electrically connected with the respective die pads 23 of the first die 20.

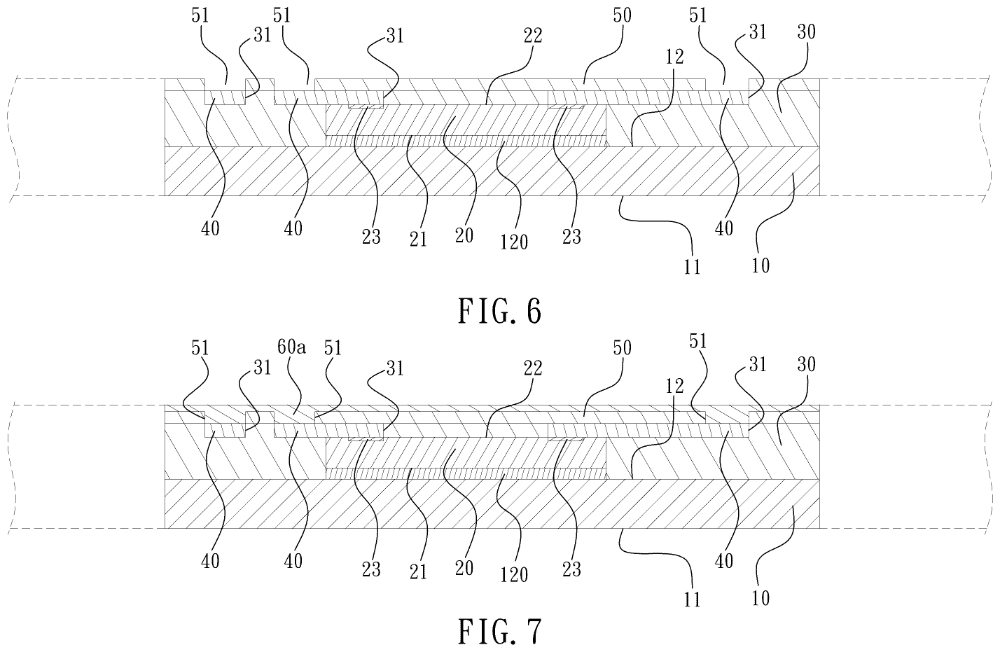

The second dielectric layer 50 is disposed over the first dielectric layer 30 and provided with a plurality of second slots 51 each of which is extending in a horizontal direction and communicating with the corresponding first slot 31, as shown in FIG. 6.

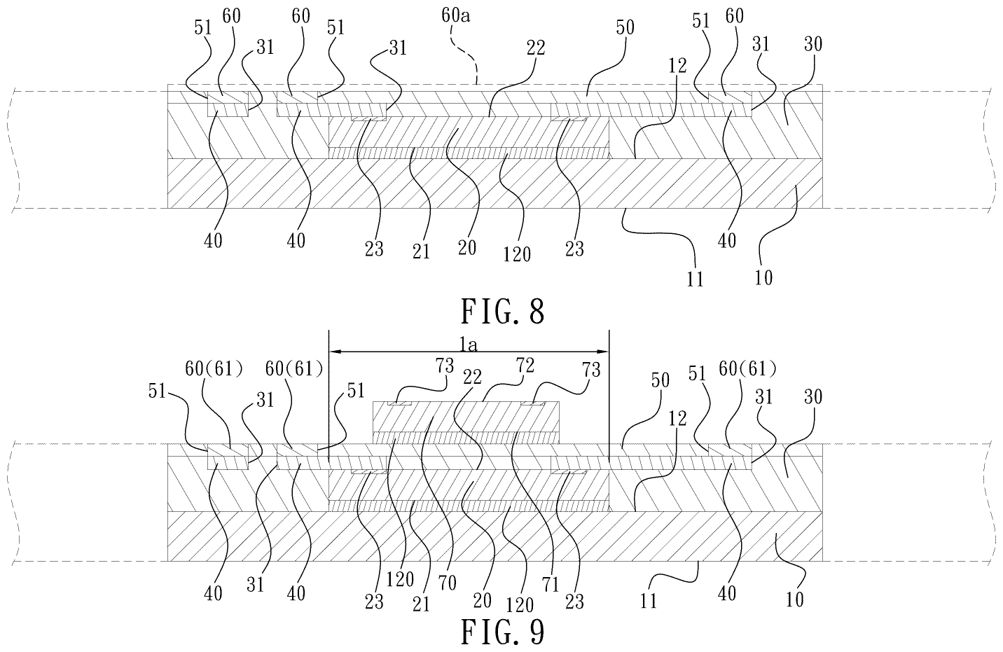

The respective second conductive circuits 60 are formed by a metal paste 60a filled in the respective second slots 51. As shown in FIG. 8, the respective second conductive circuits 60 are electrically connected with the first conductive circuits 40. At least one of the second slots 51 is located around the chip area 1a on the second surface 22 of the respective dies 20, as shown in FIG. 9. Each of the second conductive circuits 60 is exposed through the corresponding second slot 51 to form a bonding pad 60 in the second slot 51, as shown in FIG. 9. The first die 20 is electrically connected to the outside through the respective die pads 23 of the first die 20, the respective first conductive circuits 40, the respective second conductive circuits 60, and the bonding pads 61 located around the chip area 1a on the second surface 22 of the first die 20 in turn, as shown in FIG. 9.

The second die 70 is cut from a wafer and provided with a first surface 71 and a second surface 72 opposite to the first surface 21. The first surface 71 of the second die 70 is fixed on the second dielectric surface. Thereby the fan-out wafer-level packaging (FOWLP) unit 1b is formed, as shown in FIG. 9. The second surface 72 of the second die 70 is provided with a plurality of die pads 73, as shown in FIG. 9. In FIG. 9, there are two die pads 73 on the second die 70 but the number of the die pads 73 is not limited.

The electronic component 80 is provided with a first surface 81 for mounting the first surface 11 of the substrate 10, as shown in FIG. 1. The electronic component 80 can be a printed circuit board (PCB), but not limited.

The first bonding wire 90 forms a first bonding point 91 and a second bonding point 92 respectively on the bonding pad 61 and the die pad 73 of the second die 70 by a wire bonding process. Thereby an electrical connection is formed between the first die 20 and the second die 70, as shown in FIG. 1.

The second bonding wire 100 forms a third bonding point 101 and a fourth bonding point 102 respectively on the bonding pad 61 around the chip area 1a and the first surface 81 of the electronic component 80 by the wire bonding process so that both the first die 20 and the second die 70 and the electronic component 80 are electrically connected, as shown in FIG. 1.

The third bonding wire 110 forms a fifth bonding point 111 and a sixth bonding point 112 respectively on the die pad 73 of the second die 70 and the first surface 81 of the electronic component 80 by the wire bonding process so that the second die 70 and the electronic component 80 are electrically connected, as shown in FIG. 1.

Refer to FIG. 1, the bonding pads 61 can withstand a positive pressure/normal force generated during the wire bonding process or formation of the bonding points so that internal circuits will not be damaged due to the normal force. Thereby the internal circuits (such as the first conductive circuits 40) are allowed to pass through or arrange under the bonding pads 61.

A method of manufacturing the module 1 includes the following steps.

Step S1: providing a substrate 10, as shown in FIG. 2. The substrate 10 includes a first surface 11 and a second surface 12 opposite to the first surface 11, as shown in FIG. 2.

Step S2: arranging a plurality of first dies 20 cut from at least one wafer on the substrate 10 and the first dies 20 are spaced apart from one another, as shown in FIG. 2. Each of the first dies 20 includes a first surface 21 and a second surface 22 opposite to the first surface 21. The first surface 21 of the first die 20 is arranged at the substrate 10 while the second surface 22 of the first die 20 is provided with a plurality of die pads 23. A range perpendicular to the second surface 22 of the first die 20 is defined as a chip area 1a.

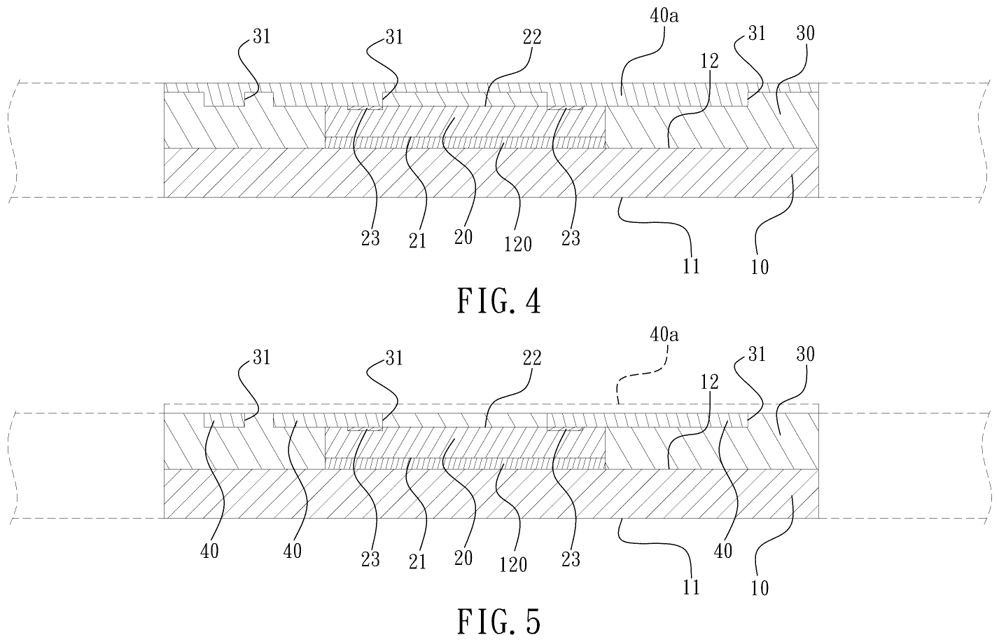

Step S3: paving a first dielectric layer 30 over the substrate 10 and the second surface 22 of the respective first dies 20 and forming a plurality of first slots 31 extending horizontally on the first dielectric layer 30 so that the respective die pads 23 of the respective first dies 20 are exposed through the respective first slots 31, as shown in FIG. 3. Then filling a metal paste 40a into the respective first slots 31 and allowing a level of the metal paste 40a higher than a surface of the first dielectric layer 30, as shown in FIG. 4. Next grinding the metal paste 40a with the level higher than the surface of the first dielectric layer 30 to make a surface of the metal paste 40a flush with the surface of the first dielectric layer 30 and form a plurality of first conductive circuits 40, as shown in FIG. 5. Later arranging a second dielectric layer 50 over the first dielectric layer 30 and forming a plurality of second slots 51 which are extending horizontally on the second dielectric layer 50 and communicating with the first slots 31 correspondingly, as shown in FIG. 6. As shown in FIG. 9, at least one of the second slots 51 is formed around the chip area 1a on the second surface 22 of the first die 20. Lastly, filling a metal paste 60a into the respective second slots 51, allowing a level of the metal paste 60a higher than a surface of the second dielectric layer 50, as shown in FIG. 7, and grinding the metal paste 60a with the level higher than the surface of the second dielectric layer 50 to make a surface of the metal paste 60a flush with the surface of the second dielectric layer 50 and form a plurality of second conductive circuits 60, as shown in FIG. 8. Each of the second conductive circuits 60 can be exposed through the corresponding second slot 51 to form a bonding pad 61 in the second slot 51, as shown in FIG. 9.

Step S4: disposing a second die 70 on the second dielectric layer 50, as shown in FIG. 9. The second die 70 includes a first surface 71 and a second surface 72 opposite to each other. The first surface 71 is fixed on the second dielectric layer 50 and the second surface 72 is provided with a plurality of die pads 73.

Step S5: performing cutting to form a plurality of fan-out wafer-level packaging (FOWLP) units 1b, as shown in FIG. 9. Each of the FOWLP units 1b includes the first die 20 and the second die 70, as shown in FIG. 9. There is one FOWLP unit 1b shown in FIG. 9 but not intended to limit the present invention.

Step S6: providing an electronic component 80 which includes a first surface 81 and disposing the first surface 11 of the substrate 10 of one of the FOWLP units 1b on the first surface 81 of the electronic component 80, as shown in FIG. 1.

Step S7: performing a wire bonding process to make at least one first bonding wire 90, at least two second bonding wires 100, and at least one third bonding wire 110 form on the FOWLP unit 1b or the electronic component 80, as shown in FIG. 1. The first bonding wire 90 forms a first bonding point 91 and a second bonding point 92 respectively on the bonding pad 61 of the first die 20 and the die pad 72 of the second die 70 of the FOWLP unit 1b. Each of the second bonding wire 100 forms a third bonding point 101 and a fourth bonding point 102 respectively on the corresponding bonding pad 61 around the chip area 1a of the FOWLP unit 1b and the corresponding electronic component 80. The third bonding wire 110 forms a fifth bonding point 111 and a sixth bonding point 112 respectively on the die pad 73 of the second die 70 and the first surface 81 of the electronic component 80. The first die 20 and the second die 70 in the FOWLP unit 1b on the electronic component 80 are electrically connected by the first bonding wire 90. Both the first die 20 and the second die 70 of the FOWLP unit 1b of the electronic component 80 are electrically connected with the electronic component 80 by the second bonding wire 100, as shown in FIG. 1. The second die 70 of the FOWLP unit 1b and the electronic component 80 are electrically connected by the third bonding wire 110. Thereby a module 1 is formed, as shown in FIG. 1.

The steps S3 of the method of manufacturing the FOWLP unit 1b is considered as a key step of manufacturing the redistribution layer (RDL) of the FOWLP unit 1b. The steps S3 is easy to be implemented precisely so that the manufacturing process is simplified and the respective first conductive circuits 40 and the respective second conductive circuits 60 in the RDL have electrical extension in the XY plane and interconnections. At the same time, the FOWLP unit 1b manufactured still has slim size and light weight to some degree.

Refer to FIG. 9, the surface of the bonding pad 61 is flush with the surface of the second dielectric layer 50, but not limited. Thereby the structure has better flatness and the wire bonding process is easy to perform to increase product reliability.

Refer to FIG. 1, the first die 20 and the second die 70 are cut from the same wafer or different wafers, but not limited. This is beneficial to diversified product development and applications.

As shown in FIG. 1, the substrate 10 includes silicon (Si) substrate, glass substrate, and ceramic substrate, but not limited.

Refer to FIG. 1, the metal paste 40a and the metal paste 60a respectively used to form the first conductive circuits 40 and the second conductive circuits 60 can be silver paste, nano-scale silver paste, copper paste, and nano-scale copper paste, but not limited. This is beneficial to diversified product development and applications. The nano-scale silver paste has features of low cost, high conductivity.

Refer to FIG. 2, the first surface 21 of the first die 20 is disposed on the substrate 10 by a die attach film (DAF) 120.

Refer to FIG. 9, the first surface 71 of the second die 70 is disposed on the substrate 10 by a die attach film (DAF) 120, but not limited.

Compared with the module containing the FOWLP unit available now, the present module 1 has the following advantages.

(1) The step S3 in the present invention is simplified and easily-implemented step and this is especially helpful in reduction of a thickness of the FOWLP unit 1b. Thus the manufacturing process of the present invention is not only more simplified with reduced cost, but also improving use efficiency and reliability of the module 1.

(2) The present method of forming the conductive circuits can effectively solve the problems of the FOWLP technology available now generated during manufacturing of the respective conductive circuits including higher manufacturing cost and less environmental benefit.

(3) As shown in FIG. 1, the first, the second, and the third bonding wires 90, 100, 110 are formed on the FOWLP unit 1b or the electronic component 80 by the wire bonding process, as shown in FIG. 1. Thus electrical connection between the chips inside or outside the packaging unit and the outside or the inside can be achieved by the wire bonding process when users need to increase performance or computing ability. The number of the dies can be increased additionally. Therefore, products with high performance or more functions can be provided.

Additional advantages and modifications will readily occur to those skilled in the art. Therefore, the invention in its broader aspects is not limited to the specific details, and representative devices shown and described herein. Accordingly, various modifications may be made without departing from the spirit or scope of the general inventive concept as defined by the appended claims and their equivalent.

1. A module containing a fan-out wafer level packaging (FOWLP) unit connected to an electronic component by wire bonding comprising:
a substrate provided with a first surface and a second surface opposite to each other;
a first die cut from a wafer and provided with a first surface and a second surface opposite to the first surface; the first surface of the first die fixed on the second surface of the substrate and the second surface of the first die provided with a plurality of die pads; a range perpendicular to the second surface of the first die being defined as a chip area;
a first dielectric layer mounted to both the second surface of the substrate and the second surface of the first die and provided with a plurality of first slots extending in a horizontal direction;
wherein the die pads of the first die are exposed through the first slots;
a plurality of first conductive circuits formed by a metal paste filled in the first slots and electrically connected to the die pads of the first die;
a second dielectric layer disposed over the first dielectric layer and provided with a plurality of second slots each of which is extending in a horizontal direction and communicating with the corresponding first slot;
a plurality of second conductive circuits formed by a metal paste filled in the second slots and electrically connected with the first conductive circuits correspondingly; wherein at least one of the second slots is located around the chip area on the second surface of the first die; wherein each of the second conductive circuits is exposed through the corresponding second slot to form a bonding pad in the second slot; wherein the first die is electrically connected to the outside through the die pads of the first die, the first conductive circuits, the second conductive circuits, and the bonding pads located around the chip area on the second surface of the first die in turn;
a second die cut from a wafer and having a first surface and a second surface opposite to each other; the first surface of the second die fixed on the second dielectric surface to form the fan-out wafer-level packaging (FOWLP) unit; wherein the second surface of the second die provided with a plurality of die pads;
an electronic component provided with a first surface for mounting the first surface of the substrate;
at least one first bonding wire forming a first bonding point and a second bonding point respectively on the bonding pad and the die pad of the second die by the wire bonding so that the first die and the second die of the FOWLP unit are electrically connected;
at least two second bonding wires each of which forms a third bonding point and a fourth bonding point respectively on the bonding pad around the chip area and the first surface of the electronic component by the wire bonding so that both the first die and the second die of the FOWLP unit are electrically connected with the electronic component;
at least one third bonding wire forming a fifth bonding point and a sixth bonding point respectively on the die pad of the second die and the first surface of the electronic component by the wire bonding so that the second die of the FOWLP unit and the electronic component are electrically connected;
wherein a method of manufacturing the module comprising the steps of:
Step S1: providing a substrate; wherein the substrate includes a first surface and a second surface opposite to the first surface;
Step S2: arranging a plurality of first dies cut from at least one wafer at the substrate and the first dies are spaced a part from one another;
wherein each of the first dies includes a first surface and a second surface opposite to the first surface; the first surface of the first die is arranged at the substrate while the second surface of the first die is provided with a plurality of die pads; a range perpendicular to the second surface of the first die is defined as a chip area;
Step S3: paving a first dielectric layer over the substrate and the second surface of the first dies and forming a plurality of first slots extending horizontally on the first dielectric layer so that the die pads of the first die are exposed through the first slots; filling a metal paste into the first slots, allowing a level of the metal paste higher than a surface of the first dielectric layer, and grinding the metal paste with the level higher than the surface of the first dielectric layer to make a surface of the metal paste flush with the surface of the first dielectric layer and form a plurality of first conductive circuits; later arranging a second dielectric layer over the first dielectric layer and forming a plurality of second slots which are extending horizontally on the second dielectric layer and communicating with the first slots correspondingly; at least one of the second slots is formed around the chip area on the second surface of the first die; lastly, filling a metal paste into the second slots, allowing a level of the metal paste higher than a surface of the second dielectric layer, and grinding the metal paste with the level higher than the surface of the second dielectric layer to make a surface of the metal paste flush with the surface of the second dielectric layer and form a plurality of second conductive circuits; each of the second conductive circuits is exposed through the corresponding second slot to form a bonding pad in the second slot;
Step S4: disposing a second die on the second dielectric layer; wherein the second die includes a first surface and a second surface opposite to each other; the first surface of the second die is fixed on the second dielectric layer and the second surface of the second die is provided with a plurality of die pads;
Step S5: performing cutting to form a plurality of fan-out wafer-level packaging (FOWLP) units each of which includes the first die and the second die;
Step S6: providing an electronic component which includes a first surface and disposing the first surface of the substrate of one of the FOWLP units on the first surface of the electronic component; and
Step S7: performing wire bonding to make at least one first bonding wire, at least two second bonding wires, and at least one third bonding wire form on the FOWLP unit or the electronic component; wherein the first bonding wire forms a first bonding point and a second bonding point respectively on the bonding pad of the first die and the die pad of the second die of the FOWLP unit; wherein the second bonding wire forms a third bonding point and a fourth bonding point respectively on the bonding pad around the chip area of the FOWLP unit and the electronic component; wherein the third bonding wire forms a fifth bonding point and a sixth bonding point respectively on the die pad of the second die and the first surface of the electronic component; wherein the first die and the second die in the FOWLP unit on the electronic component are electrically connected by the first bonding wire; wherein the first die and the second die of the FOWLP unit on the electronic component are electrically connected with the electronic component by the second bonding wire; wherein the second die of the FOWLP unit and the electronic component are electrically connected by the third bonding wire; thereby the module is formed.

2. The module as claimed in claim 1, wherein the electronic component is a printed circuit board (PCB).

3. The module as claimed in claim 1, wherein a surface of the bonding pad is flush with the surface of the second dielectric layer.

4. The module as claimed in claim 1, wherein the first die and the second die are cut from the same wafer or different wafers.

5. The module as claimed in claim 1, wherein the substrate includes silicon (Si) substrate, glass substrate, and ceramic substrate.

6. The module as claimed in claim 1, wherein the first conductive circuit is formed by silver paste, nano-scale silver paste, copper paste, and nano-scale copper paste.

7. The module as claimed in claim 1, wherein the second conductive circuit is formed by silver paste, nano-scale silver paste, copper paste, and nano-scale copper paste.

8. The module as claimed in claim 1, wherein the first surface of the first die is disposed on the substrate by a die attach film (DAF).

9. The module as claimed in claim 1, wherein the first surface of the second die is disposed on the substrate by a die attach film (DAF).
